(19) United States
(12) Patent Application Publication
(10) Pub. No.: US 2014/0347046 A1
(43) Pub. Date: Nov. 27, 2014

(54) USE OF FLEXIBLE MAGNETIC THIN LAYER SENSOR ELEMENTS

(71) Applicants: LEIBNIZ-INSTITUT FUER FESTKOERPER-UND WERKSTOFFFORSCHUNG DRESDEN E.V., Dresden (DE); TECHNISCHE UNIVERSITAET DRESDEN, Dresden (DE)

(72) Inventors: Falk Bahr, Dresden (DE); Henry Barth, Dresden (DE); Wilfried Hofmann, Dresden (DE); Denys Makarov, Dresden (DE); Michael Melzer, Dresden (DE); Ingolf Moench, Freital (DE); Martin Oppermann, Dresden (DE); Oliver G. Schmidt, Dresden (DE); Thomas Zerna, Dresden (DE)

(21) Appl. No.: 14/361,170

(22) PCT Filed: Nov. 28, 2012
(86) PCT No.: PCT/EP2012/073785

§ 371 Date: Aug. 15, 2014

(30) Foreign Application Priority Data
Nov. 29, 2011 (DE) 10 2011 087 342.2

(51) Int. Cl. G01R 33/07; G01R 33/02

(52) U.S. Cl. CPC G01R 33/07; G01R 33/02
USPC 324/251; 324/244

(57) ABSTRACT

The invention concerns the field of electrical, materials and mechanical engineering and relates to the use of flexible magnetic thin layer sensor elements, which can be used for measuring magnetic flux density in electromagnetic energy converters and magnetomechanical energy converters. The aim of the invention is to specify the use of flexible magnetic thin layer sensor elements in electric machines and magnetic bearings, which can be placed in air gaps without substantially limiting the air gap widths. Said aim is achieved by the use of at least one flexible magnetic thin layer sensor element, which is attached to non-planar surfaces in the air gap on at least one of the main elements of electromagnetic energy converters and magnetomechanical energy converters and at least partially covers the non-planar surface of at least one of the main elements in the air gap in order to measure the magnetic flux density in the air gap and/or to regulate and/or monitor electromagnetic energy converters and magnetomechanical energy converters.

The invention concerns the fields of electrical engineering, materials engineering and mechanical engineering and relates to the use of flexible magnetic thin layer sensor elements which can be used for measuring magnetic flux density in electromagnetic energy converters and magnetomechanical energy converters.

Currently, elastic electronic components are being studied extensively, since they are of interest for a broad application and offer the possibility of still adapting their shape to the test object after their production. Specifically, elastic optoelectronic components (Kim et al., Nature Mater. 2010, 9, 929-937), elastic magnetic components (Melzer et al., Nano Letters 2011, 11, 2522-2526), and elastic electronic components (Kim et al., Nature Mater. 2011, 10, 316-323) are being studied at the present time. In the case of elastic magnetic components, extensible magnetic sensor elements with an extension of up to 4.5% are known (Melzer et al., Nano Letters 2011, 11, 2522-2526).

For measuring the maximum air gap induction present in electric machines or magnetic bearings, rigid, non-deformable sensors are known which utilize the Hall effect. For these applications, the sensor thickness is of particular importance, which is at least 250 μm plus 150 μm for the contacting to conduct away the signal.

Furthermore, various studies are known for the use of rigid Hall sensors in rotating applications (Bleuler et al., Automatica Vol. 30 No. 5, pp. 871-876) and non-rotating (Yi et al., Proceedings of the 34th Conference on Decision and Control, New Orleans 1995) applications.

For the flux-based regulation of asynchronous motors, the use of micro-electromechanical systems (MEMS) was also proposed (Nerguizian et al., European Micro and Nano Systems, EMN 2004, Paris ISBN: 2-84813-037-7).

The disadvantage of these known solutions is that relatively large air gap widths must be present in order to accommodate the sensor elements. Furthermore, it is disadvantageous that the lateral extension of the rigid sensor elements can only be small. This also leads to a mere dot-shaped measuring of the air gap induction and does not necessarily yield sufficiently accurate results over the field in the entire air gap.

Furthermore, it is known to measure the air gap induction via sensor coils which are wound around the magnetic bearing stator pole or around the stator tooth of an electric machine (Schweitzer, G. et al.: Magnetic Bearings. Theory, Design and Application to Rotating Machinery. Springer, Berlin, 2009)

The object of the present solution is to specify the use of flexible magnetic thin layer sensor elements in electric machines and magnetic bearings which can be placed in the air gaps without significantly limiting the air gap width.

The object is attained by the invention disclosed in the claims. Advantageous embodiments are the subject matter of the dependent claims.

According to the invention, at least one flexible magnetic thin layer sensor element, which is attached to non-planar surfaces in the air gap on, or at, at least one of the main elements of electromagnetic energy converters and magnetomechanical energy converters and at least partially covers the non-planar surface of at least one of the main elements in the air gap, is used to measure the magnetic flux density in the air gap and/or to regulate and/or monitor electromagnetic energy converters and magnetomechanical energy converters on the basis of the measured magnetic flux density.

Advantageously, flexible magnetic thin layer sensor elements are used which are arranged in the air gap on, or at, at least one of the main elements, such as a stator or rotor, of rotating electric machines.

Likewise advantageously, flexible magnetic thin layer sensor elements are used which are arranged in the air gap on, or at, at least one of the main elements, such as a primary part or secondary part, of linear electric machines.

Also advantageously, flexible magnetic thin layer sensor elements are used which are arranged in the air gap on, or at, at least one of the main elements, such as a stator or rotor, of magnetic bearings.

And also advantageously, flexible magnetic thin layer sensor elements are which are arranged in the air gap on, or at, at least one of the main elements, such as a primary part or secondary part, of non-contact energy transmissions.

It is also advantageous if flexible magnetic thin layer sensor elements are used which achieve an at least 5%, advantageously an up to 95%, coverage of the non-planar surface.

It is likewise advantageous if flexible magnetic thin layer sensor elements with dimensions of at least a 0.1-mm width and at least a 0.1-mm length and at least a 1-μm thickness are used.

Additionally, it is advantageous if multiple flexible magnetic thin layer sensor elements are used which are arranged next to one another and/or on top of one another on the non-planar surface.

It is also advantageous if two symmetrically arranged flexible magnetic thin layer sensor elements are used.

It is also advantageous if a magnetic thin layer sensor element on a flexible substrate, advantageously of polymers or Si, is used.

And it is likewise advantageous if a flexible magnetic thin layer sensor element of layers is used which contain at least one magnetic layer, which layers are advantageously made of Co, Ni, Fe and/or alloys thereof or Heusler alloys, advantageously Fe₃Si, Cu₂MnAl.

It is also advantageous if flexible magnetic thin layer sensor elements of one or multiple multilayer systems are used which contain at least one magnetic material, advantageously Co/Cu, Py/Cu and/or Cu/Ru.

And it is also advantageous if flexible magnetic thin layer sensor elements of at least 0.5-nm thick layers are used.

It is also advantageous if flexible magnetic thin layer sensor elements are used as a Hall sensor on the basis of Bi or semiconducting materials.

With the present invention, it becomes possible for the first time to reliably measure the magnetic flux density in an air gap of electromagnetic energy converters and magnetomechanical energy converters, without significantly limiting the air gap widths determined by the device and/or to monitor and/or regulate electromagnetic energy converters and magnetomechanical energy converters on the basis of the measured values. The measurement of the magnetic flux density in the air gap can be used advantageously for various regulating tasks. In magnetic bearings, the regulation of the radial rotor position and axial rotor position can be facilitated. In electric machines, the highly dynamic field-oriented regulation can be improved. For bearingless motors, support of the combined regulation of radial bearing and the rotor angle of the rotor is possible. Last but not least, the measured magnetic flux density can be used to monitor electric machines.

The air gap is thereby the region or the space between surfaces of the main elements of rotating electric machines or linear electric machines or of magnetic bearings or non-contact energy transmissions, wherein the surfaces conduct the magnetic flux. The magnetic flux thereby serves to produce a magnetic force and/or a torque in the rotating electric machines and/or linear electric machines and/or magnetic bearings and/or non-contact energy transmissions.

The arrangement according to the invention of the magnetic thin layer sensor elements always occurs on at least one main element in the air gap of electromagnetic energy converters and magnetomechanical energy converters However, the arrangement according to the invention of the magnetic thin layer sensor elements can also occur on two of the three main elements, for example on the two stator assemblies, in the air gap of electromagnetic energy converters and magnetomechanical energy converters with more than two main elements, for example a rotor and two stator assemblies.

Within the scope of the invention, a magnetic thin layer sensor element is to be understood as meaning that this sensor element is used for measuring the magnetic flux density. Whether the thin layer sensor element is thereby fully or partially made of magnetic materials is thereby irrelevant.

Furthermore, within the scope of the invention, the flexible magnetic thin layer sensor element is to be understood as meaning a sensor element which, in its entirety, has a mechanical flexibility, that is, in which not only the support material, but also the sensor element itself, including integrated electric leads and encapsulating layers, is mechanically flexible.

Within the scope of this invention, electromagnetic energy converters are to be understood as meaning electric machines, active magnetic bearings, bearingless machines and non-contact inductive energy transmissions. Magnetomechanical energy converters are to be understood as meaning passive magnetic bearings within the scope of this invention. The solution according to the invention is to be applied to rotating electric machines and linear electric machines, non-contact inductive energy transmissions, and active magnetic bearings and passive magnetic bearings.

Electric machines can function as a motor or generator and perform either rotatory motions or linear motions.

Electric machines can thereby be subdivided into rotating electric machines, such as an electric motor or generator, linear electric machines, such as a linear motor, and stationary electric machines, such as transformers.

Rotating electric machines, linear electric machines and active magnetic bearings are electromagnetic energy converters.

Passive magnetic bearings are magnetomechanical energy converters.

A bearingless machine is an electric machine, wherein the bearing of the rotor or of the carriage occurs contactlessly by means of magnetic forces, without the presence of a separate magnetic bearing. The stator of the bearingless machine contains the windings for generating the torque and the windings for generating the carrying force for the bearing. A bearingless machine can perform rotating motions or linear motions or both motions.

The measurement results of the measurement of the magnetic flux density and, advantageously, of the air gap induction through the use according to the invention of the flexible magnetic thin layer sensor elements can be used in rotating electric machines and linear electric machines, non-contact inductive energy transmissions and active magnetic bearings for regulating and/or monitoring and in passive magnetic bearings for monitoring. Magnetic bearings can thereby perform the bearing of the moved main element (rotor or carriage).

With the magnetic bearings, differentiation occurs between “passive magnetic bearings” and “active magnetic bearings.” Passive magnetic bearings only have permanent magnets. Active magnetic bearings have at least one electromagnet and can also comprise permanent magnets. In active magnetic bearings, the position of the part that is to be borne (rotor or carriage) is regulated by an electromagnet.

The measurement of the magnetic flux density, such as the air gap induction, is attained according to the invention in that at least one flexible magnetic thin layer sensor element is permanently positioned on the non-planar surface of at least one of the device elements bordering the air gap.

The flexible magnetic thin layer sensor elements are known per se. Due to their low layer thickness as a thin layer component which typically have a layer thickness within the range of 1 to 100 μm, you only require little room in air gaps of electromagnetic energy converters and magnetomechanical energy converters, which usually have air gap widths of 0.3 mm to 1 mm, and thus limit the available air gap width only slightly to very slightly. It is even possible, with the solution according to the invention, to decrease the air gap of electromagnetic energy converters and magnetomechanical energy converters to under 0.3 mm, without the performance and service life of the electromagnetic energy and magnetomechanical energy converter being reduced.

An advantage of the solution according to the invention is that large regions of a non-planar surface in the air gap can be covered with the thin layer sensor element, and that the magnetic flux density can thus essentially be measured completely in the air gap. As a result, the influence of locally differing flux densities due to changes in the geometry of the device elements that form the non-planar surfaces, such as the stator pole or the stator tooth, can be eliminated for measuring. Similarly, air gap widths which are inconsistent due to production conditions can lead to flux density differences, the influence of which is then likewise eliminated by the solution according to the invention.

With active magnetic bearings, a regulation is necessary for positioning objects (rotor or carriage) that are to be borne. For this purpose, the air gap induction is measured by the magnetic thin layer sensor element used according to the invention, and the position of the rotor/carriage is determined by a separate position-measuring system. Based on both of these factors, it is possible to position the rotor in a stable manner. This can be achieved with one or multiple regulators.

For rotating electrical machines or linear electric machines, the air gap induction measured by the thin layer sensor element used according to the invention can be used for monitoring on the one hand and on the other hand for flux regulation.

A further advantage of the solution according to the invention is that it can also be used in devices with permanent magnets.

With the use according to the invention of the flexible magnetic thin layer sensor element, the magnetic flux density, advantageously the air gap induction, for example in magnetic bearings, is measured and the measured values can be used for regulating the position of the object (for example, rotor) to be borne or for monitoring the magnetic bearing. A flux-based regulation of this type, which is based on the determined measured values of the air gap induction, can provide an increase in the dynamic bearing parameters of rigidity and attenuation within the control circuit bandwidth and leads to a considerably higher sturdiness of the bearing with respect to parameter fluctuations.

With the use according to the invention of the flexible magnetic thin layer sensor element, the magnetic flux density, advantageously the air gap induction, is measured in rotating electric machines or linear electric machines, and the measured values can be used for regulating the rotatory motion (torque and/or rotational speed and/or rotation angle) and/or for monitoring.

With the use according to the invention of the flexible magnetic thin layer sensor element, the magnetic flux density, advantageously the air gap induction, is measured and the measured values can be used for regulating the rotatory motion (torque and/or rotational speed and/or rotation angle) and for regulating the position of the object (for example, rotor) to be borne and/or for monitoring bearingless motors.

With the use according to the invention of the flexible magnetic thin layer sensor element, the magnetic flux density, advantageously the air gap induction, is measured in non-contact inductive energy transmissions and the measured values can be used for regulating the energy transmission (current and/or voltage on the primary side and/or the secondary side) and/or for monitoring.

With the solution according to the invention, the influences of leakage fluxes and effects of a delayed magnetic flux buildup due to eddy currents can be eliminated for regulating, whereby regulating the magnetic flux without a flux-monitor structure or estimator structure becomes possible and the monitoring of machines of this type is facilitated.

The flexible magnetic thin layer sensor elements are positioned in the air gap in a positive fit and/or in a materially bonded manner, as a change in position thereof during measuring would lead to an incomparable measurement result. Advantageously, the thin layer sensor elements can be adhered to the non-planar surface. The thin layer sensor elements are electrically contacted for supply and for capturing measured data. Provided that the flexible magnetic thin layer sensor element performs the measurement on the basis of the Hall effect, the Hall voltage is measured. In the case of measurement on the basis of the magnetic impedance effect, the electric resistance is measured.

The magnetic impedance effect describes the change of the complex resistance of a magnetic material when a magnetic field is applied. The magnetic impedance effect thereby includes all magnetic resistance effects, such as the anisotropic magnetoresistance effect (anisotropic magnetoresistance AMR), giant magnetoresistance effect (giant magnetoresistance GMR), the tunnel magnetoresistance effect (tunnel magnetoresistance TMR) and the giant magnetoimpedance effect (giant magnetoimpedance GMI).

As magnetic materials with a magnetic impedance effect, all known materials can be used which
have a magnetoimpedance effect (MI) and/or a giant magnetoimpedance effect (GMI), such as FeCoBSi alloys,
have an anisotropic magnetoresistance effect (AMR), such as the elementary magnets Fe, Ni, Co and the alloys thereof,
have a giant magnetoresistance effect (GRM), such as Co/Cu, Py/Cu, Fe/Cr layer systems
which have a tunnel magnetoresistance effect (TMR), such as Fe/Al₂O₃/Fe layers, Fe/MgO/Fe layers,
have a colossal magnetoresistance effect, such as LaMnO₃.

In addition to the advantage of the low height of the thin layer sensor element, a further advantage of the solution according to the invention is its flexibility, which make a deformation, bending and/or extending of the thin layer sensor element possible during the application, adaptation and during use. As a result, the thin layer sensor element can be adapted to non-planar surfaces of electric machines, non-contact inductive energy transmissions or magnetic bearings without a problem and functions securely and reliably. The thin layer sensor elements can thereby be attached both to the stator or to the rotor or to a primary part or secondary part of the magnetic bearing, the electric machine or the non-contact inductive energy transmission. The specific shape of the non-planar surface is thereby essentially irrelevant, as are the roughness or the porosity of the non-planar surface, for example.

It is advantageous if the flexible magnetic thin layer sensor element is applied to the non-planar surface over the largest possible area. In this manner, a reliable measurement result is achieved. Also, distortions of the electric field that are particularly caused by isolated and structured elements in the air gap are avoided. With the sensor elements, the measurement of the magnetic air gap flux densities can occur in the entire working region of the magnetic bearings, electric machines or non-contact inductive energy transmissions.

The invention is explained below in greater detail with the aid of an exemplary embodiment.

### EXAMPLE 1

An anti-adhesive layer of photoresist (AZ® 5214E) is spun onto a silicon wafer (Si(100) wafer) having a 101-mm diameter and a thickness of 0.5 mm for 35 seconds at 3500 revolutions per minute and cured for 5 minutes at 120° C. on a heating plate. A mixture (10:1) of poly(dimethylsiloxane) (PDMS) and a crosslinking agent (Sylgard® 184) is then spun on at 4000 revolutions per minute for 35 seconds. This gel-like polymer mixture is cured for an hour at 120° C. in a drying oven, wherein a 20-μm thick elastic polymer film (rubber film) forms. During the subsequent cooling (to room temperature) of the PDMS film on the Si(100) wafer, the thermal contraction of the elastic polymer (rubber) is diminished by the solid silicon wafer, since the thermal expansion coefficients of the two materials differ markedly (9.6*10⁻⁴ K⁻¹ for PDMS and 2.6*10⁻⁶ K⁻¹ for silicon). In this manner, a thermally induced extension of the elastic polymer film is achieved. This elastic polymer film is the flexible substrate.

On the pre-extended polymer surface, a Hall layer system as thin layer sensor element of 2 nm of chromium (adhesive layer)+70 nm of bismuth (Hall layer)+3 nm of tantalum (cover layer) is deposited. This layer stack has a Hall effect that can be used to measure magnetic fields perpendicular to the film plane. The PDMS film coated in such a manner is cut at a right angle to 20 mm*10 mm on the Si(100) wafer (according to the dimensions of the stator pole surfaces) and these films are removed from the wafer. During the removal of the polymer layer from the wafer, the extension that was thermally induced beforehand relaxes, which results in a contraction of the polymer film. Through the contraction, a structure of folds forms in the non-compressible sensor layer lying thereupon. These folds protect the sensor layer from damage due to the mechanical stress during the bending of the thin layer sensor element. This ultimately leads to the pliability of the thin layer sensor element on the flexible substrate. After the bonding of the sensor layer system in a Hall geometry (four wires in a rectangular arrangement), a PDMS layer with the previously indicated parameters is again spun on in order to achieve an encapsulation of the thin layer sensor element.

This thin layer sensor element is then adhered to the curved surface of the stator pole of a radial magnetic bearing over the entire surface (50 μm adhesive layer) and serves as an induction sensor in the very small air gap of 350 μm. Here, the magnetic bearing is a radial bearing premagnetized as a permanent magnet, having a homopolar premagnetization flux and a heteropolar control flux. It is composed of two laminated stators for respectively four stator poles (10-mm stator length, 40-mm inner diameter, 90-mm outer diameter). The stator poles are respectively wrapped with coils. The stator poles have respectively a width of 20 mm. The four permanent magnets (10-mm length) are arranged between the two stators respectively at the outer diameter in alignment with the stator poles. The permanent magnets are designed in a segment shape (70-mm inner diameter, 90-mm outer diameter, 45° angle). The outer diameter of the rotor is 39.3 mm, so that an air gap width of 350 μm results. The rotor is composed of the rotor shaft (19.3-mm diameter) and the laminated rotor core (19.3-mm inner diameter, 39.3 mm outer diameter).

With the adhesive layer, the thin layer sensor element positioned in the air gap of the radial magnetic bearing has a total thickness of 150 μm. The mechanical air gap width has not been significantly limited by the use according to the invention of the flexible magnetic thin layer sensor element. The sensor technology integrated on the stator pole supplies the measured air gap induction, which can be returned as a control variable of a cascade structure of linear bearing controllers with underlying flux regulation or for a flux-assisted model-based regulation.

1. Use of at least one flexible magnetic thin layer sensor element, which is attached to non-planar surfaces in the air gap on, or at, at least one of the main elements of electromagnetic energy converters and magnetomechanical energy converters and at least partially covers the non-planar surface of at least one of the main elements in the air gap, for measuring the magnetic flux density in the air gap and/or for regulating and/or monitoring electromagnetic energy converters and magnetomechanical energy converters.

2. Use according to claim 1 of flexible magnetic thin layer sensor elements which are arranged in the air gap on, or at, at least one of the main elements, such as a stator or rotor, of rotating electric machines.

3. Use according to claim 1 of flexible magnetic thin layer sensor elements which are arranged in the air gap on, or at, at least one of the main elements, such as a primary part or secondary part, of linear electric machines.

4. Use according to claim 1 of flexible magnetic thin layer sensor elements which are arranged on, or at, at least one of the main elements, such as a stator or rotor, of magnetic bearings.

5. Use according to claim 1 of flexible magnetic thin layer sensor elements which are arranged on, or at, at least one of the main elements, such as a primary part or secondary part, of non-contact energy transmissions.

6. Use according to claim 1 of flexible magnetic thin layer sensor elements which achieve an at least 5%, advantageously an up to 95% coverage of the non-planar surface.

7. Use according to claim 1 of flexible magnetic thin layer sensor elements with dimensions of at least a 0.1-mm width and at least a 0.1-mm length and at least a 1-μm thickness.

8. Use according to claim 1 of multiple flexible magnetic thin layer sensor elements which are arranged next to one another and/or on top of one another on the non-planar surface.

9. Use according to claim 1 of two symmetrically arranged flexible magnetic thin layer sensor elements.

10. Use according to claim 1 of a magnetic thin layer sensor element on a flexible substrate, advantageously of polymers or Si.

11. Use according to claim 1 of a flexible magnetic thin layer sensor element of layers which contain at least one magnetic layer, which layers are advantageously made of Co, Ni, Fe and/or alloys thereof or Heusler alloys, advantageously Fe₃Si, Cu₂MnAl.

12. Use according to claim 11 of flexible magnetic thin layer sensor elements of one or multiple multilayer systems which contain at least one magnetic material, advantageously Co/Cu, Py/Cu and/or Cu/Ru.

13. Use according to claim 1 of flexible magnetic thin layer sensor elements of at least 0.5-nm thick layers.

14. Use according to claim 1 of flexible magnetic thin layer sensor elements as Hall sensor on the basis of metal materials, such as bismuth, or semiconducting materials.
